(19) United States
(12) Patent Application Publication
(10) Pub. No.: US 2026/0231432 A1
(43) Pub. Date: Aug. 6, 2026

(54) SEMICONDUCTOR DEVICE AND METHOD FOR FABRICATING THE SAME

(71) Applicant: SK hynix Inc., Gyeonggi-do (KR)

(72) Inventors: Young Ki CHAI, Gyeonggi-do (KR); Jung Hyeok KWAK, Gyeonggi-do (KR); Tae Yup KIM, Gyeonggi-do (KR); Ku Youl JUNG, Gyeonggi-do (KR); Jin Won JUNG, Gyeonggi-do (KR)

(21) Appl. No.: 19/258,905

(22) Filed: Jul. 3, 2025

(30) Foreign Application Priority Data
Feb. 3, 2025 (KR) 10-2025-0013135

(51) Int. Cl. H10B 61/00; H10N 50/01; H10N 50/10

(52) U.S. Cl. CPC H10B 61/10; H10N 50/01; H10N 50/10

(57) ABSTRACT

A semiconductor device, and a method for fabricating the same, the semiconductor device including a variable resistance memory layer. The memory layer includes a plurality of MTJ patterns including a plurality of magnetic layer patterns and tunnel barrier layer patterns that are formed over a substrate, and a self-assembled monolayer (SAM) pattern disposed between the MTJ patterns, the SAM pattern having a tapered structure.

### CROSS-REFERENCE TO RELATED APPLICATIONS

The present application claims priority under 35 U.S.C 119(a) to Korean Patent Application No. 10-2025-0013135, filed on Feb. 3, 2025, which is incorporated herein by reference in its entirety.

### BACKGROUND

### 1. Field

Various embodiments of the present disclosure relate to a semiconductor technology, and more particularly, to a semiconductor device including a Magnetic Tunnel Junction (MTJ) structure, and a method for fabricating the semiconductor device.

### 2. Description of the Related Art

The growing demand for miniaturization, energy efficiency, high performance, and the diversification of electronic devices necessitates the development of advanced semiconductor technologies capable of reliable data storage across a broad spectrum of applications, including computers, portable communication devices, and similar systems. Both researchers and industry leaders are actively engaged in efforts to innovate and design semiconductor devices that address these evolving requirements. Among such advancements are devices that exploit the ability to switch between distinct resistance states in response to variations in applied voltage or current. These include cutting-edge technologies like Resistive Random Access Memory (RRAM), Phase-change Random Access Memory (PRAM), Ferroelectric Random Access Memory (FRAM), Magnetic Random Access Memory (MRAM), E-fuses, and other related solutions, each contributing to the progress of modern electronic systems.

### SUMMARY

Embodiments of the present disclosure are directed to a semiconductor device capable of preventing (i) limitations in securing process margins due to an ion beam etching (IBE) process used in a patterning process of a general magnetic tunnel junction (MTJ) layer, (ii) limitations in the incident angle of an argon (Ar) beam, electrical short circuit defects (SFR) of the MTJ pattern, and (iii) physical damage to the sidewalls of the MTJ. Embodiments of the present disclosure further include a method for fabricating the semiconductor device. The method for fabricating the semiconductor device may include using a self-assembled monolayer (SAM) and patterning the MTJ layer without an ion beam etching (IBE) operation.

In accordance with an embodiment of the present disclosure, a semiconductor device includes a variable resistance memory layer, wherein the memory layer includes a plurality of Magnetic Tunnel Junction (MTJ) patterns including a plurality of magnetic layer patterns and tunnel barrier layer patterns that are formed over a substrate; and a self-assembled monolayer (SAM) pattern disposed between the MTJ patterns and having a tapered structure.

In accordance with an embodiment of the present disclosure, a semiconductor device includes a variable resistance memory layer, wherein the memory layer includes a plurality of MTJ patterns including a plurality of magnetic layer patterns and tunnel barrier layer patterns that are formed over a substrate; and a SAM pattern disposed between the MTJ patterns and including octadecyltrichlorosilane (ODTS).

In accordance with another embodiment of the present disclosure, a method for fabricating a semiconductor device includes forming a self-assembled monolayer (SAM) layer over a substrate; forming a SAM pattern by irradiating a portion of the SAM layer with laser light; and forming an MTJ pattern selectively including a magnetic layer pattern and a tunnel barrier layer pattern between the SAM patterns.

In accordance with another embodiment of the present disclosure, a method for fabricating a semiconductor device includes forming a photoresist pattern over a substrate; forming a SAM pattern between the photoresist patterns; removing the photoresist pattern and forming an MTJ pattern selectively including a magnetic layer pattern and a tunnel barrier layer pattern between the SAM patterns.

In accordance with another embodiment of the present disclosure, a method for fabricating a semiconductor device includes forming a self-assembled monolayer (SAM) pattern over a substrate by an inkjet printing process; and forming an MTJ pattern selectively including a magnetic layer pattern and a tunnel barrier layer pattern between the SAM patterns.

These and other features and advantages of the embodiments of the present disclosure will become apparent to those skilled in the art from the following detailed description in conjunction with the following drawings.

### BRIEF DESCRIPTION OF THE DRAWINGS

FIGS. 1A to 1F are cross-sectional views illustrating a semiconductor device and a method for fabricating the same in accordance with an embodiment of the present disclosure.

FIGS. 2A to 2F are cross-sectional views illustrating a semiconductor device and a method for fabricating the same in accordance with another embodiment of the present disclosure.

FIGS. 3A to 3C are cross-sectional views illustrating a semiconductor device and a method for fabricating the same in accordance with yet another embodiment of the present disclosure.

### DETAILED DESCRIPTION

Hereinafter, various embodiments of the present disclosure will be described in detail with reference to the attached drawings.

The embodiments of the present disclosure may be embodied in different other forms and should not be construed as being limited only to the embodiments set forth herein. Rather, these embodiments are provided so that this disclosure will be thorough and complete, and will fully convey the scope of the present disclosure to those skilled in the art. Throughout the present disclosure, like reference numerals may refer to like parts throughout the various figures and embodiments which are illustrated.

The drawings are not necessarily to scale and in some instances, proportions may have been exaggerated to clearly illustrate features of the embodiments. When a first layer is referred to as being “on” a second layer or “on” a substrate, it not only refers to a case where the first layer may be formed directly on the second layer or the substrate but also a case where a third layer may exist between the first layer and the second layer or the substrate.

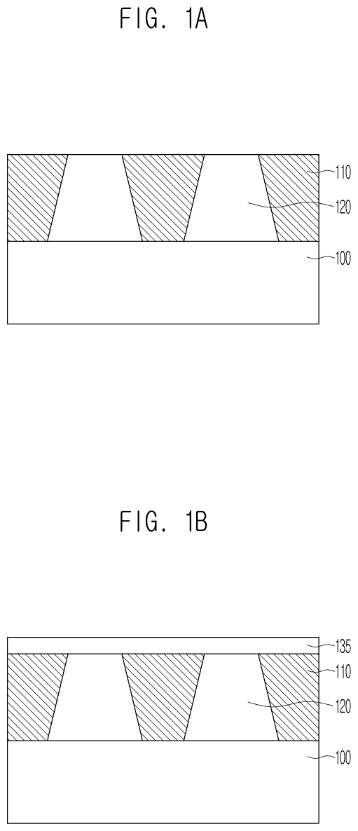

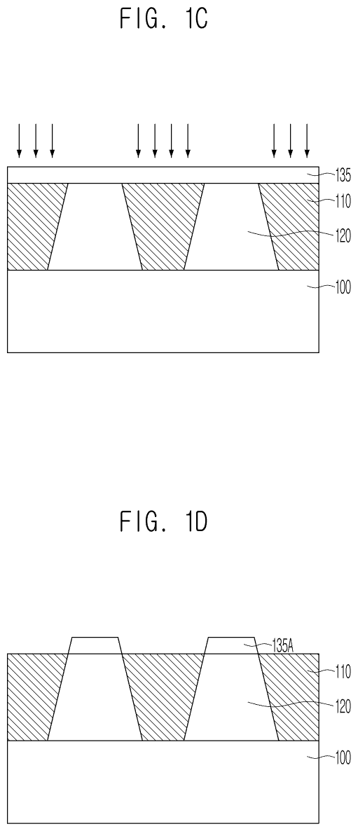

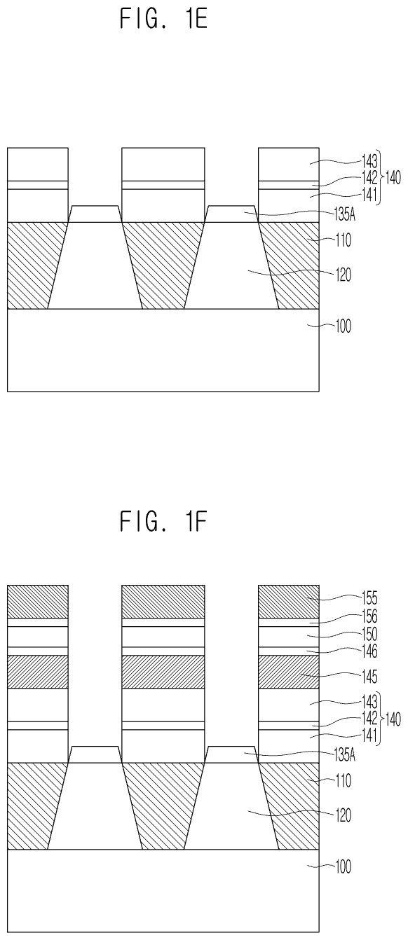

FIGS. 1A to 1F are cross-sectional views illustrating a semiconductor device and a method for fabricating the same in accordance with an embodiment of the present disclosure.

Referring to FIG. 1A, a lower electrode contact 110 may be formed over a substrate 100 where a predetermined lower structure (not shown) is formed. The substrate 100 may include a semiconductor material, for example, silicon and the like. Also, a required predetermined lower structure (not shown) may be formed in the substrate 100. For example, an integrated circuit for driving a first conductive line and/or a second conductive line, for example, a word line and/or a bit line, may be formed in the substrate 100. The lower electrode contact 110 may be formed by forming an inter-layer dielectric layer 120 having a hole over the substrate 100, forming a material layer for forming the lower electrode contact 110 in the hole, and then performing a planarization process, for example, a chemical mechanical planarization process. For example, the inter-layer dielectric layer 120 may have a plurality of holes and a plurality of spaced apart lower electrode contacts 110 may be formed as shown in FIG. 1A. The inter-layer dielectric layer 120 may include a dielectric material, polysilicon (Poly-Si), or a combination thereof. The inter-layer dielectric layer 120 may be formed as a single-layer structure or a multi-layer structure. For example, the inter-layer dielectric layer 120 may include silicon oxide, silicon nitride, silicon oxynitride, and/or a low-k material. A material having a dielectric constant (k) of approximately 4 or less may be generally referred to as a low-k material. As the value of the dielectric constant (k) becomes smaller, the electrical insulation characteristics improve, and the parasitic capacitance between elements decreases. The low-k material may include, for example, silicon oxide, organic siloxane, silicon carbide, an organic-based material including a benzene ring or fluorine, and a void material, but the embodiments of the present disclosure are not limited thereto.

This process may be performed by creating a hole of a precise size at a location where a lower electrode contact 210 is disposed through a photolithography process and an etching process, and filling the hole with a material layer for the lower electrode contact 210. The material for the lower electrode contact 210 may include tungsten (W), titanium (Ti), tantalum (Ta), vanadium (V), chromium (Cr), platinum (Pt), aluminum (Al), copper (Cu), zinc (Zn), nickel (Ni), cobalt (Co), lead (Pd), manganese (Mn), niobium (Ni), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), or a combination thereof.

Referring to FIG. 1B, a self-assembled monolayer (SAM) layer 135 may be formed over the planarized lower electrode contact 110 and the inter-layer dielectric layer 120.

The process of forming the self-assembled monolayer (SAM) layer 135 may include first removing any contaminants from that part of the surface on which the SAM layer 135 is to be formed. Removing the contaminant may include performing at least one of a plasma treatment, an oxide etching process, or a solvent washing process on the surface where the SAM layer 135 is to be formed. Subsequently, a hydroxyl (—OH) group may be formed on the surface to activate the molecules of the SAM material to be bonded. The SAM material may be applied to the surface portion where the SAM layer 135 is to be formed by diluting the SAM material in an appropriate solvent, such as ethanol or toluene, to prepare a solution, and immersing the structure of FIG. 1A in the solution or spin-coating the solution. The SAM material may include, for example, an alkylsilane, a thiol, or a carboxylic acid, and the alkylsilane may include octadecyltrichlorosilane (ODTS). Subsequently, the SAM material may be deposited in a vapor phase to be adsorbed onto the surface. Here, the SAM material may be aligned and chemically bonded while being adsorbed onto the surface to form the SAM layer 135. A stable monolayer structure may be formed by the van der Waals force or a chemical interaction between the molecules.

For example, the SAM material may be octadecyltrichlorosilane ODTS (C₁₈H₃₇SiCl₈). The ODTS may have the following chemical formula:

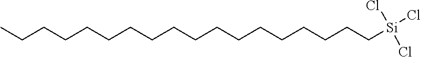 [SMILES: CCCCCCCCCCCCCCCCCC[Si](Cl)(Cl)Cl]

The silane group (—SiCl₃) of the ODTS may react with the surface on which a hydroxyl (—OH) group is formed, such as silicon oxide (SiO₂), glass or an oxide, to form a Si—O—Si bond, and the long alkyl chain (—C₁₈H₃₇) may provide a hydrophobic surface. The ODTS may form a self-assembled monolayer (SAM) layer 135 over the lower electrode contact 110 and the inter-layer dielectric layer 120. The thickness of the formed SAM layer 135 may range from approximately 1 to approximately 10 nm. In an embodiment, the thickness of the formed SAM layer 135 may range from approximately 2 to approximately 3 nm. When the thickness of the self-assembled monolayer (SAM) layer 135 is too thin, mechanical defects or non-uniformity may increase. Additionally, the molecules of the SAM material may not be sufficiently aligned or uniform. For example, when the thickness of the self-assembled monolayer (SAM) layer 135 is less than approximately 1 nm, mechanical defects or non-uniformity may increase, and the molecules of the SAM material may not be sufficiently aligned or uniform. When the thickness of the SAM layer 135 is too thick, the single layer structure may break down, and a multi-layer may be formed. For example, when the thickness of the SAM layer 135 is more than approximately 10 nm, the single layer structure may break down, and a multi-layer may be formed, which may cause non-uniformity and deterioration in performance, and may interfere with the formation of the upper layer.

Since the ODTS has a long hydrocarbon chain of 18 carbon atoms, ODTS may provide hydrophobic characteristics to the self-assembled monolayer layer 135. Also, the terminal trichlorosilane (SiCl₃) group may form a strong chemical bond with the surface to which it is bonded. Here, the surface energy may be lowered, which effectively suppresses the attachment of a particular substance, such as a metal or an oxide, so that the MTJ pattern 140 may not be deposited thereon. Also, the SiCl₃ functional group of the ODTS may form a strong Si—O—Si bond with the oxidized surface to be bonded so that the formed SAM layer 135 may be stable and has excellent thermal/chemical durability. The ODTS may be able to ensure high reproducibility in a miniaturized nano-patterning process by forming a highly aligned single layer based on the self-assembly characteristics on the surface to provide a uniform thickness, for example, several nanometers, and precise surface characteristics. Also, since ODTS is easily dissolved in a solvent and the SAM layer 135 may be formed by simple immersion or spin coating, it is possible to realize ODTS without additional complex equipment, and material costs may also be reduced in a large-scale process.

Referring to FIGS. 1C and 1D, a SAM pattern 135A may be formed by selectively irradiating laser light to the SAM layer 135 disposed over the lower electrode contact 110 where an MTJ pattern 140 is to be formed. Here, the generated SAM pattern 135A may have a tapered structure, as the byproducts generated by the decomposition of the SAM layer 135 due to the irradiation of the laser light are redistributed to the peripheral area.

Since the MTJ pattern (140 of FIG. 1E) is to be formed over the lower electrode contact 110, the laser light may be selectively irradiated to the portion where the MTJ pattern 140 is to be formed. The laser used for selective etching of the SAM layer 135 may be one among an excimer laser, a femtosecond laser, and a Nd: YAG laser. The excimer laser may provide a high-power ultraviolet (UV) light source and induce a photochemical reaction of the SAM layer 135 for decomposition. The excimer laser may also be suitable for forming a precise pattern and may minimize the influence of heat. Here, the wavelength used may be approximately 193 nm (ArF) or approximately 248 nm (KrF). The femtosecond laser may provide a very high energy density locally and may remove the SAM layer 135 in a non-thermal manner. Since the femtosecond laser does not cause thermal damage to the surrounding layer, it may be more effective in protecting the lower electrode contact 110. Here, the pulse duration may have a unit of approximately 10 to 13 seconds. The Nd: YAG laser may have a basic wavelength of approximately 1064 nm (visible light or infrared ray), and the basic wavelength may be converted to approximately 532 nm (double frequency), approximately 355 nm (triple frequency), and the like.

When the laser is irradiated in a patterned manner on the formed SAM layer 135, a photochemical reaction, such as decomposition or sintering, may occur to form a self-assembled monolayer (SAM) pattern 135A. After the selective laser irradiation, the residual SAM layer 135 may be removed by a chemical method, such as a solvent cleaning, to completely remove the portion which is unnecessary for forming the MTJ pattern 140.

Referring to FIG. 1E, since the region where the MTJ pattern 140 is to be formed is defined by forming the SAM pattern 135A, the MTJ pattern 140 may be formed in this region through a subsequent process, such as deposition or lithography.

The MTJ pattern 140 may be formed by sequentially depositing materials for forming a fixed layer pattern 141, a tunnel barrier layer pattern 142, and a free layer pattern 143. The MTJ pattern 140 is not formed over the SAM pattern 135A but is only selectively deposited between the SAM patterns 135A because of the characteristics of the SAM pattern 135A. Specifically, characteristics such as the difference in the surface energies, chemical inertness, and physical blocking between the SAM pattern 135A and the surface of the lower electrode contact 110 prevent deposition of the MTJ pattern on the SAM pattern 135A. Hence, the SAM pattern 135A serves as a mask during the process and distinguishes a region where the MTJ pattern 140 is to be formed and a region where the MTJ pattern 140 is not to be formed from each other. This may allow the MTJ pattern 140 to be formed only in the region between the SAM patterns 135A.

Since the SAM pattern 135A has a very low surface energy or is formed of organic molecules capable of controlling the surface characteristics, the material for forming the MTJ pattern 140 to be deposited may not attach to the upper portion of the SAM pattern 135A or, even though some of the material is deposited, it may not grow uniformly. As a result, the molecules deposited over the SAM pattern 135A may not be adsorbed but may be diffused to the peripheral area or removed. Also, the SAM material of the SAM pattern 135A may include a specific functional group so as not to be bonded with metal atoms or a compound used in the deposition process. For example, a SAM material formed of a nonpolar alkyl group (—CH₃) may be resistant to the deposition of a metal or the formation of an oxide. The SAM pattern 135A may be a self-assembled organic monolayer, and the molecules may form a structure in which the upper surface has a deposition resistance while forming a strong bond with the lower substrate. When the SAM material of the SAM pattern 135A is strongly bonded to the substrate, deposition of an additional material onto the upper portion may be physically blocked. For example, when the hydrophobic molecules of the SAM pattern 135A are formed over a hydrophilic substrate, the surface may be hydrophobic, which may prevent deposition of a metal or an oxide.

The memory layer including the MTJ pattern 140 may function to store data in diverse ways. For example, the memory layer may include a variable resistance layer that stores different data by switching between different resistance states according to the voltage or current supplied through the upper and lower portions of the memory layer. The variable resistance layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM), and the like, for example, metal oxides such as transition metal oxides, perovskite-based materials and the like, phase-change materials such as chalcogenide-based materials and the like, ferroelectric materials, ferromagnetic materials, and the like.

The free layer pattern 143 and the fixed layer pattern 141 may include a material having an interface perpendicular magnetic anisotropy. The interface perpendicular magnetic anisotropy refers to a phenomenon in which a magnetic layer having intrinsic horizontal magnetization characteristics has a vertical magnetization direction due to the influence from the interface with another neighboring layer. Here, the intrinsic horizontal magnetization characteristics may refer to the characteristics in which the magnetic layer has a magnetization direction which is parallel to the widest surface of the magnetic layer when there is no external factor.

For example, when the magnetic layer having intrinsic horizontal magnetization characteristics is formed over the substrate and there is no external factor, the magnetization direction of the magnetic layer may be substantially parallel to the upper surface of the substrate. Each of the free layer pattern 143 and the fixed layer pattern 141 may have a single-layer structure or a multi-layer structure including a ferromagnetic material. The ferromagnetic material may include an alloy containing Fe, Ni or Co as a main component, such as, for example, an Fe—Pt alloy, an Fe—Pd alloy, a Co—Fe alloy, a Co—Pd alloy, a Co—Pt alloy, a Co—Fe—Ni alloy, an Fe—Ni—Pt alloy, a Co—Fe—Pt alloy, a Co—Ni—Pt alloy, or a Co—Fe—B alloy. In some embodiments, the ferromagnetic material may include a stacked structure such as, for example, Co/Pt, Co/Pd, Fe/Pt, Fe/Pd, Ni/Pt, or Ni/Pd. The positions of the free layer pattern 143 and the fixed layer pattern 141 may be switched with each other with the tunnel barrier layer pattern 142 interposed between them. In a variation of the embodiment illustrated in FIG. 1E, the free layer pattern 143 may be disposed below the tunnel barrier layer pattern 142, and the fixed layer pattern 141 may be disposed over the tunnel barrier layer pattern 142. The tunnel barrier layer pattern 142 may enable tunneling of electrons between the free layer pattern 143 and the fixed layer pattern 141 during a write operation that changes the resistance state of the variable resistance element, thereby changing the magnetization direction of the free layer pattern 143. The tunnel barrier layer pattern 142 may include at least one of an oxide of magnesium (Mg), an oxide of titanium (Ti), an oxide of aluminum (Al), an oxide of magnesium-zinc (MgZn), an oxide of magnesium-boron (MgB), a nitride of titanium (Ti), and a nitride of vanadium (V). For example, the tunnel barrier layer pattern 142 may be a single layer of magnesium oxide (MgO). Also, the tunnel barrier layer pattern 142 may include a plurality of layers. The free layer pattern 143, the tunnel barrier layer pattern 142, and the fixed layer pattern 141 may form an MTJ pattern 140.

Also, in some embodiments, an intermediate layer pattern (not shown) may be further formed between the fixed layer 141 and the tunnel barrier layer 142. The intermediate layer pattern may be a magnetic layer which is closest to the tunnel barrier layer pattern 142 and may include Co, Fe, Ni, B, a noble metal, or a combination thereof.

The electrical resistance of the MTJ pattern 140 may depend on the magnetization directions of the fixed layer pattern 141 and the free layer pattern 143. For example, the electrical resistance of the MTJ pattern 140 may be much larger when the magnetization directions of the fixed layer pattern 141 and the free layer pattern 143 are antiparallel than when the magnetization directions of the fixed layer pattern 141 and the free layer pattern 143 are parallel. As a result, the electrical resistance of the MTJ pattern 140 may be controlled by changing the magnetization direction of the free layer pattern 143, which may be used as a data storage principle in the semiconductor device in accordance with an embodiment of the present disclosure.

Referring to FIG. 1F, a selector pattern 150 may be additionally formed over the MTJ pattern 140. The selector pattern 150 may include an Ovonic Threshold Switching (OTS) material such as a diode, a chalcogenide-based material and the like, a Mixed Ionic Electronic Conducting (MIEC) material such as a metal-containing chalcogenide-based material, a Metal Insulator Transition (MIT) material such as niobium dioxide (NbO₂), vanadium dioxide (VO₂), and the like, or a tunneling dielectric material having a relatively wide band gap such as silicon dioxide (SiO₂), aluminum dioxide (Al₂O₃) and the like. Prior to forming the selector pattern 150, a first electrode layer pattern 145 and a silicon nitride (SiN) thin layer 146 may be sequentially formed. Thereafter, the selector pattern 150 may be formed over the silicon nitride thin layer 146. Subsequently, a carbon (C) thin layer 156 and a second electrode layer pattern 155 may be sequentially formed over the selector pattern 150.

Also, the selector pattern 150 may include a dielectric material containing a dopant which is implanted by an ion implantation process. For example, the dielectric material may include a silicon-containing dielectric material such as silicon oxide, silicon nitride, silicon oxynitride and the like, a dielectric metal oxide, a dielectric metal nitride, or a combination thereof. The dopant may serve to create trap sites that capture conductive carriers migrating in the dielectric material or provide a path for the captured conductive carriers to migrate again. To form the trap sites, diverse elements that generate an energy potential capable of accepting the conductive carriers in the dielectric material may be used as the dopant. For example, when the dielectric material includes a silicon-containing dielectric material, the dopant may include a metal whose valance is different from the valance of silicon, such as aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination thereof. Also, when the dielectric material includes a dielectric metal oxide or a dielectric metal nitride, the dopant may include a metal whose valance is different from the valance of the metal of the metal oxide or metal nitride, or silicon. For example, the selector pattern 150 may include silicon dioxide (SiO₂) into which arsenic (As) is implanted by an ion implantation process. When a voltage which is equal to or higher than a threshold voltage is applied to the selector pattern 150, an on-state in which current flows through the selector pattern 150 may be realized by migrating the conductive carriers through the trap sites. When the voltage applied to the selector pattern 150 is decreased to less than the threshold voltage, an off-state in which current does not flow because the conductive carriers do not migrate may be realized.

The selector pattern 150 may be implemented as a thin layer in the memory cell and may function to control electrical access to one memory cell among a plurality of arrayed memory cells, while preventing current leakage that may occur between the memory cells that share a first interconnection or a second interconnection. To this end, the selector pattern 150 may have the threshold switching characteristics of blocking off the current or holding the current to hardly flow when the level of the voltage supplied to the upper and lower portions of the selector pattern 150 is lower than a predetermined threshold voltage, and then letting the current rapidly flow at a voltage level which is equal to or higher than the threshold voltage. The selector pattern 150 may be turned on at a voltage level which is equal to or higher than the threshold voltage and may be turned off at a voltage level which is lower than the threshold voltage. For example, the selector pattern 150 may include a dielectric material into which a dopant is implanted.

Also, the layer structure of the memory cell MC including the MTJ pattern 140 and the selector pattern 150 may not be limited to what is illustrated in the figures. For example, in variations of the illustrated embodiment, the stacking order of the layers may be changed, and/or one or more among the layers may be omitted, and/or one or more layers may be added. For example, one or more among the first to third electrode layer patterns may be added below the MTJ pattern 140, between the MTJ pattern 140 and the selector pattern 150, and over the selector pattern 150. The sidewalls of the selector pattern 150 and the first to third electrode layer patterns may be self-aligned due to the SAM pattern 135A. Also, the positions of the MTJ pattern 140 and the selector pattern 150 may be switched with each other. Also, one or more layers (not shown) may be added to the memory cell MC to improve the process or the characteristics of the memory cell MC. For example, FIG. 1F illustrates a stack structure in which the first electrode layer pattern 145, the silicon nitride thin layer 146, the selector pattern 150, the carbon thin layer 156, and the second electrode layer pattern 155 are sequentially stacked in this order.

Also, the first electrode layer pattern 145 and the second electrode layer pattern 155 may include a titanium nitride (TiN) thin layer, and may further include a silicon nitride (SiN) thin layer 146 at the interface between the first electrode layer pattern 145 and the selector pattern 150, and a carbon (C) thin layer 156 at the interface between the selector pattern 150 and the second electrode layer pattern 155. Each of the silicon nitride (SiN) thin layer 145 and the carbon (C) thin layer 146 may increase the chemical stability of the interface and prevent physical damage. The silicon nitride (SiN) thin layer 146 may have excellent electrical insulation and chemical durability, and may suppress the interface reaction, such as oxidation or diffusion, between the first electrode layer pattern 145 and the selector pattern 150, and the carbon thin layer 156 may have excellent heat resistance and abrasion resistance, and may reduce mechanical damage and prevent interface deterioration at the interface between the selector pattern 150 and the second electrode layer pattern 155. The silicon nitride (SiN) thin layer 146 may have a thickness ranging from about 1 nm to about 10 nm, which is sufficient to form a reliable barrier to oxidation and ion diffusion while maintaining minimal parasitic capacitance. The carbon (C) thin layer 156 may have a thickness ranging from about 1 nm to about 5 nm, which ensures high conductivity and thermal resistance without increasing the series resistance or degrading switching performance. Also, the silicon nitride (SiN) thin layer may minimize current leakage with excellent insulating characteristics, decrease electrical noise by stabilizing the electrostatic capacitance of the interface, and the carbon thin layer may efficiently maintain the current flow between the selector pattern 150 and the second electrode layer pattern 155 by providing low electrical resistance and high conductivity.

As a result of the above process, a semiconductor device in accordance with an embodiment of the present disclosure may be formed including a substrate 100, a lower electrode contact 110, an MTJ pattern 140 including a fixed layer pattern 141, a tunnel barrier layer pattern 142 and a free layer pattern 143, and a selector pattern 150 as shown in FIG. 1F.

This embodiment of the present disclosure proposes a method of forming the MTJ pattern 140 after forming the SAM pattern 135A. This method for fabricating a semiconductor device may solve the problems occurring in the general ion beam etching (IBE) process and may also improve the characteristics of the MTJ pattern 140. The general method of patterning the MTJ pattern 140 may form the MTJ pattern 140 that is patterned using the IBE process. However, this method may have limitations in performing a precise etching process due to insufficient process margin, poor electrical short circuit (SFR), damage to the sidewall of the MTJ pattern 140, formation of a tapered MTJ pattern 140, and the limitation in the incident angle of an argon (Ar) beam in a narrow pitch region.

The method using the general IBE process may have a problem in that the sidewall of the MTJ pattern 140 may be damaged or physically destroyed due to a high-energy argon (Ar) beam frequency. This damage may deteriorate the electrical characteristics and structural stability of the MTJ pattern. On the other hand, since the IBE process is not used in the embodiment of the present disclosure, damage to the sidewall of the MTJ pattern 140 may be prevented. As a result, electrical short circuit (SFR) defects may be decreased, which may improve the reliability of the MTJ pattern 140. Also, in the general IBE process, the electrical short circuit (SFR) problem may occur frequently due to fine defects which may occur during the patterning process. The short circuit may cause a performance deterioration of the formed MTJ pattern and a high defect rate in the fabrication process. On the other hand, according to the described embodiment of the present disclosure, the IBE process may be removed to drastically reduce the SFR defects, and as a result, the electrical reliability of the MTJ pattern 140 may be improved.

Also, in the general IBE process, there may be a problem in that the etching precision becomes low and a tapered MTJ pattern 140 is formed due to the limitation in the incident angle of the argon (Ar) beam in a narrow pitch region. This may act as a major obstacle in the design of a high-density MTJ array. On the other hand, according to the described embodiment of the present disclosure based on the SAM pattern 135A, such problems may be solved to form the MTJ pattern 140 with a high precision even in a narrow pitch region. This may be very advantageous for designing and fabricating high-density and miniaturized semiconductor devices. According to the embodiment of the present disclosure, the IBE process may be completely removed, and a simple process of forming the MTJ pattern 140 after forming the SAM pattern 135A may be adopted. This may not only simplify the entire process but also reduce equipment investment costs and operating costs by excluding the use of expensive equipment, such as IBE equipment. Also, the simplified process may improve productivity and provide high cost efficiency in mass production. Also, the method in accordance with the embodiment of the present disclosure using the SAM pattern 135A may stably form the MTJ pattern 140 of a smaller size by overcoming the precision limitations in the IBE process.

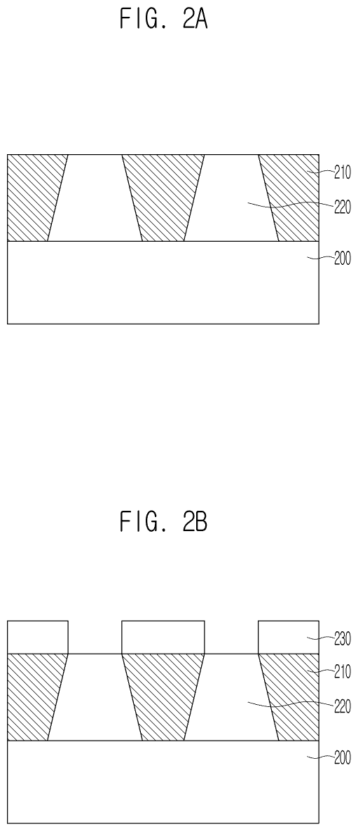

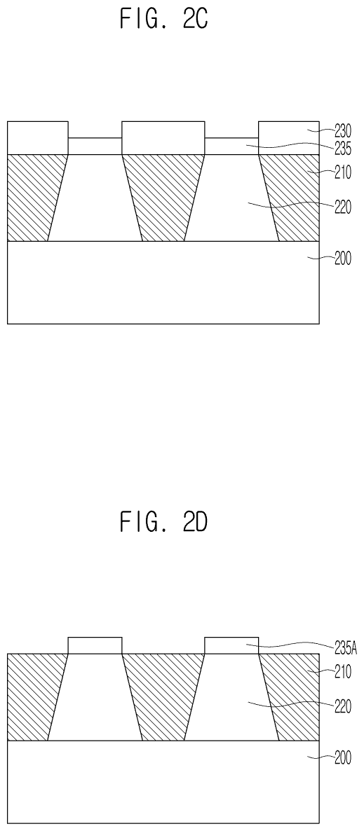

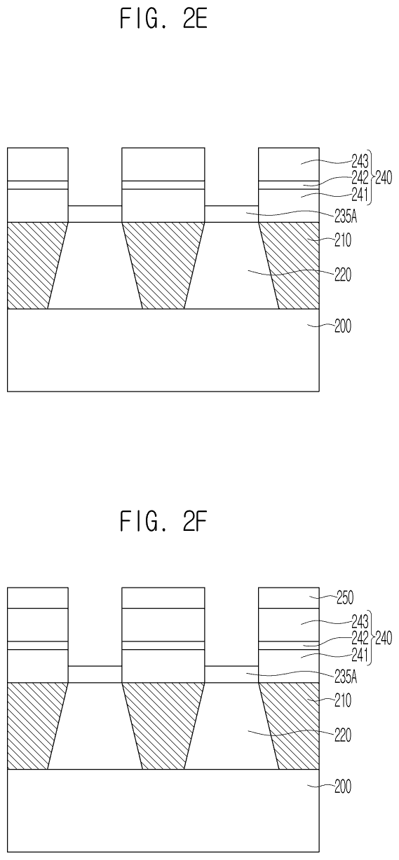

FIGS. 2A to 2F are cross-sectional views illustrating a semiconductor device and a method for fabricating the same in accordance with another embodiment of the present disclosure. For any parts that are substantially the same as the above-described embodiment of the present disclosure, a detailed description may be omitted.

Referring to FIG. 2A, an inter-layer dielectric layer 220 may be formed over a substrate 200 on which a predetermined substructure (not shown) is formed, and a lower electrode contact 210 may be formed in the hole. The substrate 200 may include a semiconductor material, for example, silicon, and the like.

Referring to FIG. 2B, a photoresist pattern 230 may be formed in a region where an MTJ pattern (240 of FIG. 2E) is to be formed, i.e., an upper region of the lower electrode contact 210.

The process of forming the photoresist pattern 230 may include a lithography process that is used to form a fine pattern over the substrate. First, a photoresist (not shown) may be applied to the lower electrode contact 210 and to the inter-layer dielectric layer 220 to have a uniform thickness. The photoresist may be applied by dropping the photoresist onto the lower electrode contact 210 and the inter-layer dielectric layer 220, and performing a spin coating process of spinning it at high speed to form a uniform thin layer. The coating thickness may be determined according to the rotation rate and the viscosity of the photoresist. The coated photoresist may be heated to be stably fixed to the surface of the lower electrode contact 210 and the inter-layer dielectric layer 220, and some of the solvent may be evaporated to increase the adhesiveness. Subsequently, a mask may be disposed over the photoresist, and ultraviolet (UV) or an electron beam (e-beam) may be irradiated to expose a particular region to light. The photoresist, which has undergone a chemical change due to the light, may be exposed to a developer to form a photoresist pattern 230. Subsequently, in order to increase the thermal stability of the photoresist pattern 230, the remaining solvent may be removed and an annealing process may be performed.

Referring to FIG. 2C, a SAM layer 235 may be formed between the photoresist patterns 230.

A hydroxyl (—OH) group may be formed on the surface where the SAM layer 235 is to be formed to activate the molecules of the SAM material to be bonded. The SAM material may be diluted in an appropriate solvent, such as ethanol or toluene, to prepare a solution, and the structure of FIG. 2B may be immersed in the solution or the solution may be spin-coated to apply the SAM material to the surface. The SAM material may include, for example, an alkylsilane, a thiol, or a carboxylic acid, and the alkylsilane may include octadecyltrichlorosilane (ODTS). Subsequently, the SAM material may be deposited in a gas phase and adsorbed onto the surface. Here, the SAM material may be adsorbed onto the surface and aligned to form a chemical bond, thereby forming the SAM layer 235. A stable single-layer structure may be formed by the van der Waals force or chemical interactions between the molecules. The thickness of the formed SAM layer 235 may range from approximately 1 to approximately 10 nm. In an embodiment, the thickness of the formed SAM layer 235 may range from approximately 2 to approximately 3 nm. When the thickness of the SAM layer 235 is too thin, for example, less than approximately 1 nm, mechanical defects or nonuniformity may increase, and the molecules of the SAM material may not be sufficiently aligned or uniform. When the thickness of the SAM layer 235 is too thick, for example, more than approximately 10 nm, the single-layer structure may be broken down, and multiple layers may be formed, which may cause nonuniformity and deterioration in the performance, and may interfere with the formation of the upper layer.

Referring to FIG. 2D, the photoresist pattern 230 may be removed to form the SAM pattern 235A. The SAM pattern 235A may be formed by completely removing the remaining photoresist pattern 230 while only a selected region of the SAM layer 235 remains. Here, a wet etching process that removes the photoresist pattern 230 with an organic solvent, such as acetone or NMP, and a dry etching process that burns and removes the photoresist pattern 230 through a plasma process, such as an O₂ plasma process, may be used to remove the photoresist pattern 230. Subsequently, a cleaning process and/or an annealing process at a low temperature of approximately 100 to 150° C. may be performed to remove a resistive residue or an etching byproduct and increase the bonding stability of the SAM pattern 235A.

Referring to FIGS. 2E and 2F, since the SAM pattern 235A is formed and thereby the region where the MTJ pattern 240 is to be formed is defined, an MTJ pattern 240 may be formed in this region through a subsequent process, such as a deposition process or a lithography process.

The MTJ pattern 240 may be formed by sequentially depositing materials for forming a fixed layer pattern 241, a tunnel barrier layer pattern 242, and a free layer pattern 243. The reason why the MTJ pattern 240 is not formed over the SAM pattern 235A but is selectively deposited only between the SAM patterns 235A is due to the characteristics of the SAM pattern 235A and, in particular, characteristics such as the surface energy, chemical inertness, and physical blocking which are very different from those of the surface of the lower electrode contact 210. Hence, the SAM pattern 235A plays an important role in distinguishing the region where the MTJ pattern 240 is formed and the region where the MTJ pattern 240 is not formed by functioning as a mask during the process. As a result, the MTJ pattern 240 may be formed only in the region between the SAM patterns 235A.

Subsequently, a selector pattern 250 may be additionally formed over the MTJ pattern 240. The selector pattern 250 may include an Ovonic Threshold Switching (OTS) material such as a diode, a chalcogenide-based material and the like, a Mixed Ionic Electronic Conducting (MIEC) material such as a metal-containing chalcogenide-based material and the like, a Metal-Insulator-Transition (MIT) material such as NbO₂, VO₂ and the like, or a tunneling dielectric material having a relatively wide band gap such as SiO₂, Al₂O₃, and the like.

Even according to this embodiment of the present disclosure as illustrated in FIGS. 2A-2F, all advantages described in the embodiment of FIGS. 1A-1F may be obtained. Namely, the method of FIGS. 2A-2E of forming the MTJ pattern 240 prevents the problems occurring in the general IBE process and improves the characteristics of the MTJ pattern 240.

Since the IBE process is not used in the embodiment of FIGS. 2A-2E, damage to the sidewall of the MTJ pattern 240 may be prevented. As a result, the reliability of the MTJ pattern 240 may be improved by reducing the electrical short circuit (SFR) defect. Also, the SFR defect may be drastically decreased by removing the IBE process, and as a result, the electrical reliability of the MTJ pattern 240 may be improved.

Also, according to the embodiment of FIGS. 2A-2E, it is possible to form the MTJ pattern 240 with high precision even in a narrow pitch region, simplify the overall process, and reduce equipment investment costs and operating costs by excluding the use of expensive devices such as IBE equipment. Also, the simplified process may improve productivity, provide high cost efficiency in mass production, and stably form the MTJ pattern 240 in a smaller size by overcoming the precision limitations in the IBE process.

The substrate 200, the lower electrode contact 210, the inter-layer dielectric layer 220, the SAM pattern 235A, the MTJ pattern 240 including the fixed layer pattern 241, the tunnel barrier layer pattern 242, and the free layer pattern 243, and the selector pattern 250 that are illustrated in FIG. 2F may correspond to the substrate 100, the lower electrode contact 110, the inter-layer dielectric layer 120, the SAM pattern 135A, the MTJ pattern 140 including the fixed layer pattern 141, the tunnel barrier layer pattern 142, the free layer pattern 143, and the selector pattern 150 that are illustrated in FIG. 1F, respectively. Therefore, a detailed description of these features of FIG. 2F may be omitted.

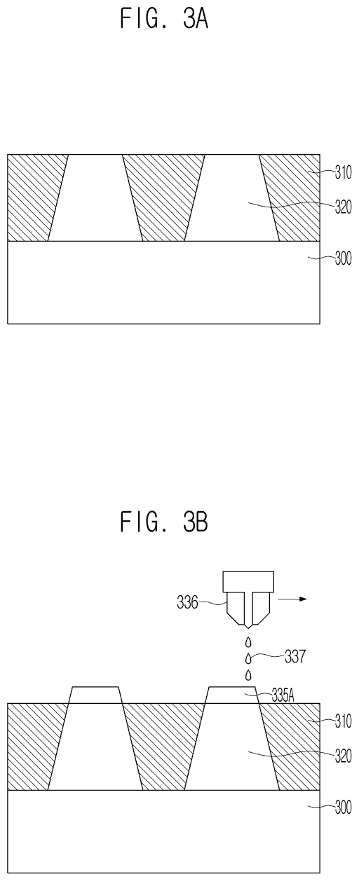

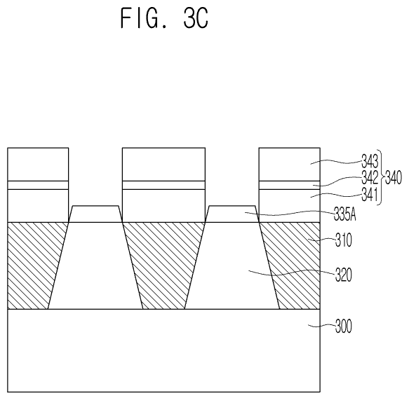

FIGS. 3A to 3C are cross-sectional views illustrating a semiconductor device and a method for fabricating the same in accordance with yet another embodiment of the present disclosure. A detailed description of the features which are substantially the same with those already described in the embodiments of FIGS. 1A-2F above may be omitted.

Referring to FIG. 3A, a lower electrode contact 310 may be formed over a substrate 300 where a predetermined lower structure (not shown) is formed. The lower electrode contact 310 may be formed by forming an inter-layer dielectric layer 320 having a hole over the substrate 300, forming a material layer for forming the lower electrode contact 310 in the hole, and then performing a planarization process, such as, for example, a chemical mechanical planarization process.

Referring to FIG. 3B, a SAM pattern 335A may be formed in the upper portion of an inter-layer dielectric layer 320 but not on the lower electrode contact 310 by performing inkjet printing using inkjet printer 336. The SAM pattern 335A may include octadecyltrichlorosilane (ODTS). Here, a plurality of droplets 337 from the inkjet printer 336 may be deposited on the surface of the inter-layer dielectric layer 320, and the SAM pattern 335A having a tapered structure may be formed based on the surface tension of the droplets 337. First, the ink may be distributed uniformly by controlling the nozzle size of the inkjet printer 336 and the spraying speed of the droplets 337. The extent that the droplets 337 naturally spread on the surface of the inter-layer dielectric layer 320 may be controlled to form the SAM pattern 335A having a tapered edge shape. Here, the surface tension, viscosity, and drying time of the ink for forming the SAM pattern 335A may be adjusted to design the tapered structure to be naturally formed. Also, the migration speed of the head of the inkjet printer 336 and the spraying cycle of the droplets 337 may be adjusted, and the substrate temperature may be adjusted to optimize the drying speed and spreading degree of the ink.

Also, the method and speed at which the ink is deposited on the surface may be changed through a surface treatment of the inter-layer dielectric layer 320. For example, the hydrophilicity or hydrophobicity of the surface may be controlled through a plasma treatment. Oxygen, argon, nitrogen, or helium may be used for the plasma treatment, and high-energy ions or activated neutral particles that are emitted from the plasma may react with the surface of the inter-layer dielectric layer 320, and in this process, the molecular structure of the surface may be changed, or general contaminants may be removed.

For example, when hydrophilic treatment is performed using oxygen plasma, the surface energy of the inter-layer dielectric layer 320 may be increased, allowing the ink to spread widely. In this case, the contact angle of the ink may be decreased, which may be advantageous for forming a uniform pattern. When hydrophobic treatment is performed using fluorine-based plasma, the surface energy of the inter-layer dielectric layer 320 may be decreased, allowing the ink to spread less and stay at a fixed location. In this case, the contact angle of the ink may be increased, which may be advantageous for forming a precise pattern.

It is preferred that the inkjet printer 336 uses a printer capable of controlling precise spray. A piezoelectric inkjet printer may be suitable because it may precisely control the size and spray speed of the droplet 337. The piezoelectric inkjet printer may include, for example, the Dimatix Materials Printer (DMP) series, MicroFab Inkjet Printer, and the like.

Referring to FIG. 3C, since the region where the MTJ pattern 340 is formed is defined by forming the SAM pattern 335A, the MTJ pattern 340 may be formed in this region through a subsequent process, such as a deposition process or a lithography process. The MTJ pattern 340 may be formed by sequentially depositing materials for forming the fixed layer pattern 341, the tunnel barrier layer pattern 342, and the free layer pattern 343.

The structure of FIG. 3C may be substantially the same as the structure of FIG. 1E described above. That is, the substrate 300, the lower electrode contact 310, the inter-layer dielectric layer 320, the SAM pattern 335A, and the MTJ pattern 340 including the fixed layer pattern 341, the tunnel barrier layer pattern 342 and the free layer pattern 343 may correspond to the substrate 100, the lower electrode contact 110, the inter-layer dielectric layer 120, the SAM pattern 135A, the MTJ pattern 140 including the fixed layer pattern 141, the tunnel barrier layer pattern 142 and the free layer pattern 143, respectively. Therefore, the process of forming the MTJ pattern 340 after the formation of the SAM pattern 335A may be performed to be substantially the same as the process for forming the structure of FIG. 1E described above.

Even according to the embodiment of FIGS. 3A-3C, all advantages described earlier may be obtained. In particular, the two-step process of laser patterning or photoresist patterning after the deposition of the SAM layer may be omitted, and the SAM pattern 335A may be formed in a single process through the inkjet printing process. This leads to an additional advantage as the process steps are decreased. The fabrication time may be decreased due to the shortened process, and the equipment and material costs required for the laser or photoresist process may be saved. Also, since chemicals used in the photoresist process or an additional cleaning process are not needed, there are further environmental and economic advantages.

Since the inkjet printing process may precisely control the size and spraying location of the droplets 337, the desired pattern may be formed with high resolution. This may reduce patterning errors that may occur in general processes and increase reproducibility. Also, whereas diverse chemicals are used in the laser patterning or photoresist process, which require waste disposal, the inkjet printing in accordance with this embodiment of the present disclosure may minimize the use of the chemicals. Moreover, the inkjet printing may allow flexible adjustment of the size, density, shape of the SAM pattern 335A so that it may be applied to diverse substrates and applications.

According to the embodiment of the present disclosure, the semiconductor device and the method for fabricating the same may secure the process margin, overcome the limitations in the incident angle of an argon (Ar) beam, and prevent electrical short-circuit defects in the MTJ pattern and physical damage to the MTJ sidewall by solving the problems occurring in the general ion beam etching (IBE) process using a self-assembled monolayer (SAM) where an MTJ layer is not deposited.

While the embodiments of the present disclosure have been described with respect to specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device comprising:
a variable resistance memory layer,
wherein the memory layer includes:
a plurality of Magnetic Tunnel Junction (MTJ) patterns including a plurality of magnetic layer patterns and tunnel barrier layer patterns that are formed over a substrate; and
a self-assembled monolayer (SAM) pattern disposed between the MTJ patterns and having a tapered structure.

2. The semiconductor device of claim 1, wherein the magnetic layer patterns include:
a free layer pattern having a changeable magnetization direction and
a fixed layer pattern having a fixed magnetization direction.

3. The semiconductor device of claim 1, further comprising:
a selector pattern disposed in upper portions or lower portions of the MTJ patterns.

4. The semiconductor device of claim 3, further comprising:
a first electrode layer pattern disposed below the selector pattern and
a second electrode layer pattern disposed over the selector pattern.

5. The semiconductor device of claim 4, wherein sidewalls of the first electrode layer pattern and the second electrode layer pattern are aligned with sidewalls of the MTJ patterns.

6. The semiconductor device of claim 4, wherein each of the first electrode layer pattern and the second electrode layer pattern includes a titanium nitride (TiN) thin layer.

7. The semiconductor device of claim 4, further comprising:
a silicon nitride (SiN) thin layer having a thickness ranging from 1 nm to 10 nm at an interface between the first electrode layer pattern and the selector pattern, and
a carbon (C) thin layer having a thickness ranging from 1 nm to 5 nm at an interface between the selector pattern and the second electrode layer pattern.

8. The semiconductor device of claim 2, further comprising:
an intermediate layer pattern interposed between the fixed layer pattern and the tunnel barrier layer pattern.

9. The semiconductor device of claim 1, wherein the SAM pattern includes octadecyltrichlorosilane (ODTS).

10. The semiconductor device of claim 1, wherein the SAM pattern has a thickness of 1 nm to 10 nm.

11. A semiconductor device comprising:
a variable resistance memory layer,
wherein the memory layer includes:
a plurality of MTJ patterns including a plurality of magnetic layer patterns and tunnel barrier layer patterns that are formed over a substrate; and
a SAM pattern disposed between the MTJ patterns and including octadecyltrichlorosilane (ODTS).

12. A method for fabricating a semiconductor device, the method comprising:
forming a self-assembled monolayer (SAM) layer over a substrate;
forming a SAM pattern by irradiating a portion of the SAM layer with a laser light; and
forming an MTJ pattern selectively including a magnetic layer pattern and a tunnel barrier layer pattern between the SAM patterns.

13. The method of claim 12, wherein the magnetic layer pattern includes:
a free layer pattern having a changeable magnetization direction and
a fixed layer pattern having a fixed magnetization direction.

14. The method of claim 12, further comprising
forming a selector pattern over the MTJ pattern.

15. The method of claim 13, further comprising
forming an intermediate layer pattern between the fixed layer pattern and the tunnel barrier layer pattern.

16. The method of claim 15, wherein the intermediate layer pattern includes Co, Fe, Ni, B, a noble metal, or a combination thereof.

17. The method of claim 14, further comprising:
forming a first electrode layer pattern below the selector pattern, and
forming a second electrode layer pattern over the selector pattern.

18. The method of claim 12, wherein the SAM layer includes octadecyltrichlorosilane (ODTS).

19. A method for fabricating a semiconductor device, the method comprising:
forming a photoresist pattern over a substrate;
forming a SAM pattern between the photoresist patterns;
removing the photoresist pattern and forming an MTJ pattern selectively including a magnetic layer pattern and a tunnel barrier layer pattern between the SAM patterns.

20. The method of claim 19, wherein removing the photoresist pattern is performed by a wet etching process or a dry etching process.

21. The method of claim 19, wherein the SAM pattern includes octadecyltrichlorosilane (ODTS).

22. A method for fabricating a semiconductor device, the method comprising:
forming a self-assembled monolayer (SAM) pattern over a substrate by an inkjet printing process; and
forming an MTJ pattern selectively including a magnetic layer pattern and a tunnel barrier layer pattern between the SAM patterns.

23. The method of claim 22, wherein the SAM patterns are formed, as a plurality of droplets are deposited onto the substrate by an inkjet printing process.

24. The method of claim 22, wherein the SAM patterns include octadecyltrichlorosilane (ODTS).

25. A semiconductor device comprising:
a variable resistance memory layer including a plurality of Magnetic Tunnel Junction (MTJ) patterns formed over a lower electrode contact;
a self-assembled monolayer (SAM) pattern disposed between the MTJ patterns, the SAM pattern having a tapered structure; and
a selector pattern formed over the MTJ patterns,
wherein the SAM pattern includes octadecyltrichlorosilane (ODTS) and has a thickness of 1 nm to 10 nm.
